(19) United States
(12) Patent Application Publication
(10) Pub. No.: US 2016/0094238 A1
(43) Pub. Date: Mar. 31, 2016

(54) APPARATUS FOR TESTING ANALOG-TO-DIGITAL CONVERTER AND TESTING METHOD THEREOF

(71) Applicant: Samsung Electro-Mechanics Co., Ltd., Suwon-Si (KR)

(72) Inventor: Jin Yong KANG, Suwon-Si (KR)

(73) Assignee: Samsung Electro-Mechanics Co., Ltd., Suwon-Si (KR)

(21) Appl. No.: 14/858,634

(22) Filed: Sep. 18, 2015

(30) Foreign Application Priority Data
Sep. 25, 2014 (KR) 10-2014-0128440

(51) Int. Cl. H03M 1/10

(52) U.S. Cl. CPC H03M 1/1071

(57) ABSTRACT

There is provided an apparatus for testing an analog-to-digital converter including: an analog-to-digital converter converting an analog type signal into a digital type signal; a signal generator applying a predetermined type analog signal to the analog-to-digital converter; a first processor controlling the signal generator so that the analog signal is divided to be applied to the analog-to-digital converter; and a second processor determining error occurrence, determining a valid range, and calculating DNL and INL of output data of the analog-to-digital converter.

### CROSS-REFERENCE TO RELATED APPLICATION

This application claims the benefit of Korean Patent Application No. 10-2014-0128440, filed on Sep. 25, 2014, entitled “Apparatus for Testing Analog-to-Digital Converter and Testing Method Thereof” which is hereby incorporated by reference in its entirety into this application.

### BACKGROUND

The present disclosure relates to an apparatus for testing an analog-to-digital converter and a testing method thereof.

An analog-to-digital converter as an apparatus that converts analog voltage into a digital code is a requisite apparatus used in a digital device by converting an analog signal into a digital signal.

As a mixed signal circuit applied to most systems, an analog-to-digital converter is provided and a self-testing method embedded for the analog-to-digital converter is actively researched. The self-testing method embedded for the analog-to-digital converter includes a static method that determining whether a failure occurs by calculating performance indexes including gain, offset, differential non-linearity (DNL), integral non-linearity (INL), and the like and a dynamic method that calculates performance indexes including a signal-to-noise ratio (SNR), signal-to-noise and distortion (SINAD), effective number of bits (ENOB), and the like.

A method which is most used among the static methods is a histogram method. A test using the histogram method is a method that applies a predetermined analog signal generated by a signal generator to an input of the analog-to-digital converter and stores, in a memory, a frequency for each code generated from an output. An offset, a gain, the INL, and the DNL are output by calculating a characteristic of the analog-to-digital converter by using the frequency of each code which is stored.

The histogram method requires a lot of samples in order to acquire a result which is statistically reliable. As a result, since a lot of storage spaces are required, a test apparatus requires a large-capacity memory.

Further, in the case of an n-bit analog-to-digital converter, the number of output data which the analog-to-digital converter can output is 2ⁿ, for example, in the case of a 3-bit analog-to-digital converter, a total of eight output data of 000 to 111 can be output. Similarly, an 8-bit analog-to-digital converter has 256 output data of 0 to 255 (hereinafter, converted into a decimal number, which is described). Accordingly, a 256 B storage space is required to measure the performance of the 8-bit analog-to-digital converter, but since a 12-bit analog-to-digital converter has 4096 output data, the performance cannot be measured by using a 4 KB memory to require the large-capacity memory. In recent years, since a lot of devices use an analog-to-digital converter having high resolution in order to process the picture or voice, a lot of storage spaces enough to store a histogram measured to measure the performance of the analog-to-digital converter are consumed.

### RELATED ART DOCUMENT

### Patent Document

(Patent Document 1) JP2001-517014 A

### SUMMARY

According to an aspect of the present disclosure, an analog signal having a plurality of measurement intervals is input into an analog-to-digital converter to store in a memory only output data of the analog-to-digital converter measured in respective measurement intervals. Accordingly, an aspect of the present disclosure may provide an apparatus for testing an analog-to-digital converter and a testing method thereof which can measure the performance of the analog-to-digital converter by using a small-capacity memory.

According to an aspect of the present disclosure, an apparatus for testing an analog-to-digital converter may include: an analog-to-digital converter; a signal generator applying an analog signal to the analog-to-digital converter; a first processor controlling the signal generator so that the analog signal is divided to be applied to the analog-to-digital converter; and a second processor determining error occurrence, determining a valid range, and calculating DNL and INL of output data of the analog-to-digital converter, and the analog signal has divided measurement intervals and a compensation interval for consecutively outputting the output data.

According to another aspect of the present disclosure, a testing method of an analog-to-digital converter may include: applying an analog signal having divided measurement intervals to the analog-to-digital converter; comparing output data of the analog-to-digital converter with a predetermined error threshold value to determine whether an error of the output data occurs and determining the number of detection times of output data included in a predetermined valid range; and calculating INL and DNL of the analog-to-digital converter based on the output data.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a diagram showing a general block diagram of an apparatus for testing an analog-to-digital converter according to a first exemplary embodiment of the present disclosure;

FIG. 2 is a diagram showing an analog signal applied to the analog-to-digital converter;

FIG. 3 is a diagram showing the number of detection times of output data of the analog-to-digital converter by a histogram; and

FIG. 4 is a testing method of an analog-to-digital converter according to a second exemplary embodiment of the present disclosure.

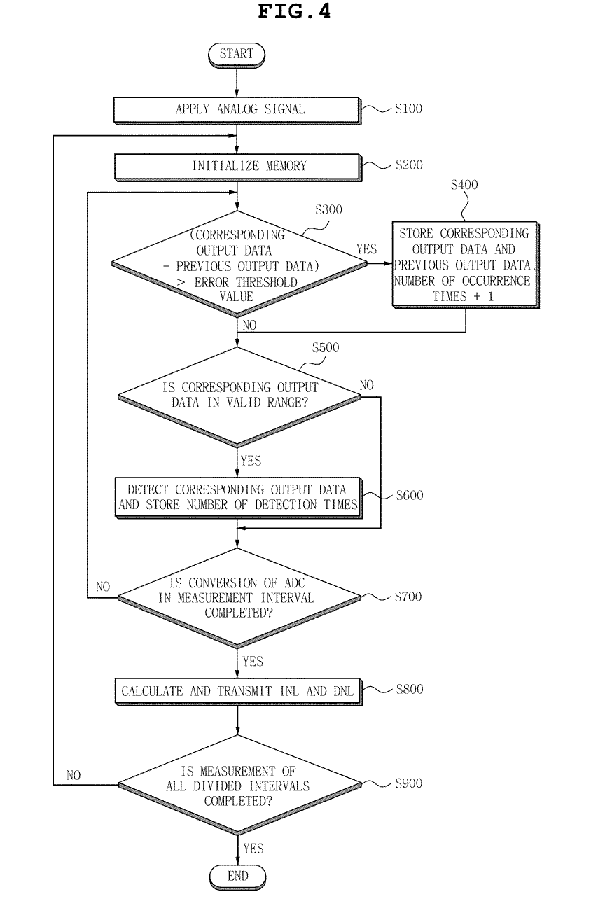

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

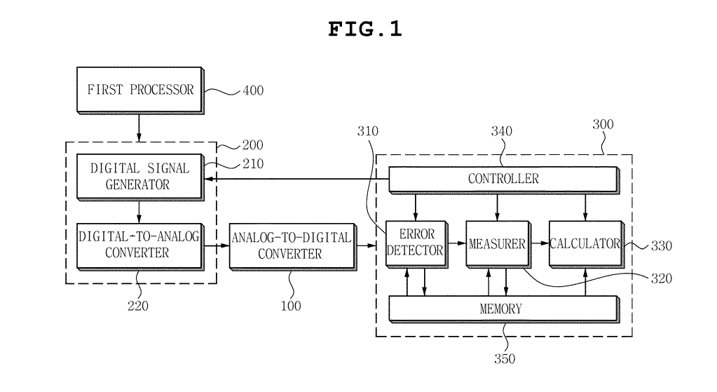

FIG. 1 is a block diagram showing an apparatus for testing an analog-to-digital converter 100 according to a first exemplary embodiment of the present disclosure. As shown in FIG. 1, the apparatus for testing the analog-to-digital converter according to the exemplary embodiment of the present disclosure includes an analog-to-digital converter 100, a signal generator 200, a first processor 400, and a second processor 300.

The analog-to-digital converter 100 as an electronic circuit that converts an analog electrical signal into a digital electrical signal primarily performs a function to convert an analog physical quantity measured by a sensor, and the like into binary digital data of “0” and “1” which may be processed by a CPU. However, since distortion of the signal may occur during converting the signal, the performance of the analog-to-digital converter 100 needs to be tested in order to determine whether the distortion occurs.

The signal generator 200 generates an analog signal having divided measurement intervals for measuring the performance of the analog-to-digital converter 100 and inputs the generated analog signal in the analog-to-digital converter 100. This is to divide a whole interval of the analog signal into a plurality of divided measurement intervals to measure the performance of the analog-to-digital converter 100 in the respective measurement intervals. Accordingly, the number of the measurement intervals is set according to a capacity of a memory 350 included in the second processor 300. Further, the measurement interval is divided based on a predetermined period to be generated, but the present disclosure is not particularly limited thereto and may be changed according to selection by those skilled in the art. The signal generator 200 includes a digital signal generator 210 and a digital-to-analog converter 220 and detailed contents thereof will be described below.

The first processor 400 controls the signal generator 200 so that the analog signal is divided to be applied to the analog-to-digital converter 100. In detail, the first processor 400 controls the signal generator 200 so as to generate an analog signal including a plurality of divided measurement intervals and a compensation interval for securing consecutive outputs of the analog-to-digital converter 100. Detailed contents thereof will also be described below.

The second processor 300 measures the output data of each measurement interval output by applying the analog signal to the analog-to-digital converter 100 and counts the number of detection times of valid output data by detecting whether an error of the measured output data occurs and only the valid output data. The performance index is calculated through a predetermined equation to be described below by using the output data and the number of detection times and thereafter, transmitted to the outside. The second processor 300 includes an error detector 310, a measurer 320, a calculator 330, a controller 340, and a memory 350 and detailed contents thereof will be described below.

The signal generator 200 generates a ramp signal having a predetermined slope value of a voltage form in the measurement interval and applies the generated ramp signal to the analog-to-digital converter 100. The analog signal is not particularly limited to the ramp signal and the analog signal which is changeable by those skilled in the art and has the same effect may be applied to the exemplary embodiment of the present disclosure.

Further, as shown in FIG. 1, the signal generator 200 may include a digital signal generator 210 generating the digital signal having the plurality of divided measurement intervals and a digital-to-analog converter (DAC) 220 converting the digital signal into the analog signal. That is, the digital signal generator 210 generates the digital signal that increases constantly with the plurality of measurement intervals and inputs the digital signal into the digital-to-analog converter (DAC) 220 to generate the ramp signal. Thereafter, the ramp signal is applied to the analog-to-digital converter 100 to test the performance of the analog-to-digital converter 100. Accordingly, when the digital signal generator 210 and the digital-to-analog converter 210 are mounted in a device, since the test is available in the device itself, a separate signal generator 200 is not required.

The first processor 400 controls the signal generator 200 so that the analog signal is divided to be applied to the analog-to-digital converter 100. The first processor 400 controls the signal generator 200 so as to apply to the analog-to-digital converter 100 an analog signal including a plurality of divided measurement intervals and a compensation interval for securing consecutive outputs of the analog-to-digital converter 100. Further, the first processor 400 performs a function to stop driving of the signal generator 200 according to whether the analog signal reaching predetermined reference voltage.

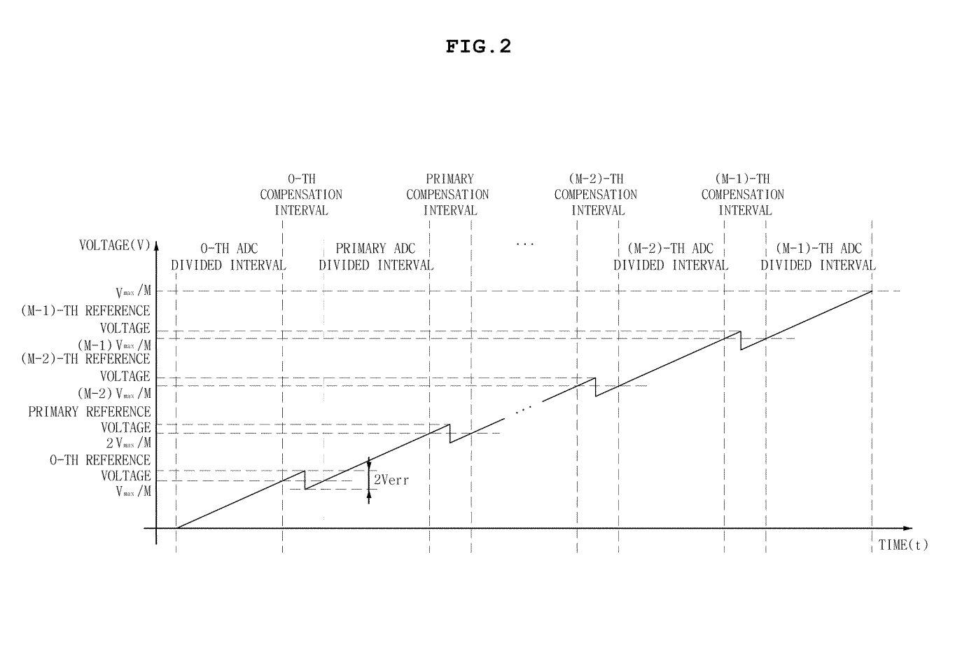

FIG. 2 is a diagram showing a waveform of the ramp signal applied to the analog-to-digital converter 100. As shown in FIG. 2, the ramp signal has a compensation interval that outputs voltage which is lower than voltage corresponding to start output data of the measurement interval by predetermined error voltage Verr and outputs voltage which is higher than voltage corresponding to end output data of the measurement interval by the error voltage Verr.

Herein, the start output data means output data which is first output among the output data of the analog-to-digital converter 100 in each measurement interval and similarly, the end output data means output data which is last output in the measurement interval. Further, the reference voltage means voltage higher than voltage corresponding to the end output data by the error voltage and when the analog signal reaches the reference voltage, generation of the analog signal is stopped by the controller 340.

In detail, the ramp signal has M measurement intervals and the voltage of the ramp signal increases from 0 V which is lowest voltage to Vmax which is highest voltage with a constant slope value as a time t elapses in the whole interval. However, at a boundary point of each measurement interval, the signal is more output or less output by the predetermined error voltage Verr, and as a result, the signal has a sawtooth wave-form waveform having a difference of double error voltage (2*Verr).

Further, the predetermined error voltage is decided by the user and means an error range value of the analog signal in which the start output data or the end output data of the corresponding measurement interval is output. For example, it is assumed that when a 10-V input voltage is applied to the analog-to-digital converter 100, the analog-to-digital converter 100 ideally outputs a 1000 code and when a 9-V input voltage is applied to the analog-to-digital converter 100, the analog-to-digital converter 100 ideally outputs a 0111 code, even though the 10-V input voltage is applied, an error occurs during a conversion process, the analog-to-digital converter 100 may output the 0111 or 1001 code. Accordingly, 9 V corresponding to the 0111 code needs to be applied in order to prevent the 1000 code from being skipped and error voltage in this case becomes 1 V which is a difference between 10 V and 9 V.

Since the analog signal considering the error voltage as described above is applied to the analog-to-digital converter 100, the compensation interval is formed between the measurement intervals as shown in FIG. 2. Applying the analog signal including the measurement interval and the compensation interval is to prevent some of the output data from being skipped by consecutively outputting the output data at the boundary point of the measurement interval. Accordingly, the analog signal includes the compensation interval to improve reliability of a test result of the analog-to-digital converter 100.

The first processor 400 controls driving of the signal generator 200 according to whether the analog signal of the signal generator 200 reaching the predetermined reference voltage. In detail, when the measurement of the analog-to-digital converter 100 is completed in a predetermined measurement interval, that is, when the analog signal shown in FIG. 2 reaches the reference voltage, the first processor 400 stops driving of the signal generator 200 and transmits a measurement completion signal to the second processor 300 through a communication port.

Thereafter, the second processor 300 starts calculation of INL and DNL which are performance indexes of the analog-to-digital converter 100 and when calculation of the corresponding measurement interval is completed, the first processor 400 drives the signal generator 200 again.

Further, the user adjusts a slope value of the ramp signal through the first processor 400 to select any one of shortening of a test time or precision of the performance index. That is, when the ramp signal is slowly increased, the precision of the performance index is improved and when the ramp signal is rapidly increased, a test time of the analog-to-digital converter 100 is shortened.

The second processor 300 determines whether the error of the output data occurs and whether the all output data of the analog-to-digital converter 100 is valid in the measurement interval by comparing the output data of the analog-to-digital converter 100 with a predetermined reference value. Further, the INL and the DNL indicating the performance of the analog-to-digital converter 100 are calculated based on the valid output data. The predetermined reference value means an error threshold value and a valid range and a detailed description thereof will be made below. Further, the second processor 300 may be a micro controller unit (MCU), but is not particularly limited thereto and may be changed to units having the same function and effect.

The second processor 300 includes the error detector 310 counting whether the error of the output data occurs and the position of output data in which the error occurs among the output data and the number of times when the error occurs, the measurer 320 counting the number of detection times by detecting only output data included in the valid range, the calculator 330 calculating the differential non-linearity (DNL) and integral non-linearity (INL) through Equations 1 to 4 given below by using the output data and the number of detection times, and the controller 340 controlling the error detector 310, the measurer 320, and the calculator 330 so as to perform determination of the error occurrence of the output data, determination of the valid range, and calculation of the DNL and the INL.

$$\begin{matrix}average\_count = {\sum }_{i = 0}^{N - 1} {count}_{total} / N \vert & [ Equation 1 ] \\ {normalized\_count}_{i} = {count}_{i} / average\_count & [ Equation 2 ] \\ {DNL}_{i} = {normalized\_count}_{i} - 1 & [ Equation 3 ] \\ {INL}_{i} = {\sum }_{i = 0}^{N - 1} {DNL}_{i} & [ Equation 4 ]\end{matrix}$$

(i=0 to N−1, N represents the total number of output data in the measurement interval and count represents the number of detection times of the output data)

In detail, the error detector 310 receives the output data output from the analog-to-digital converter 100 to acquire a difference between the corresponding output data and the previous output data. The difference and the predetermined error threshold value are compared with each other and when the difference is larger than the error threshold value, it is determined that the error of the output data occurs. When it is determined that the error occurs, the corresponding output data and the previous output data are stored in the memory 350 and the number of error occurrence times is increased by 1. When the difference of the output data is smaller than the error threshold value, it is determined that the error does not occur in the output data.

The measurer 320 determines whether all output data of the analog-to-digital converter 100 in the measurement interval is included in the predetermined valid range to count the number of detection times by detecting only the output data included in the valid range among all output data of the analog-to-digital converter 100 in the measurement interval. Herein, the valid range is set through Equations 5 and 6 given below.

Data=output data−(m*(2ⁿ/M)) [Equation 5]

(m*(2ⁿ/M))≦data≦(m+1)*(2ⁿ/M)−1

(M represents the number of all measurement intervals, m represents a degree of a measurement interval which is measured, and 0 to M−1_n represents a bit of the analog-to-digital converter 100)

When it is determined that the corresponding output data is the valid output data included in the valid range, a result value (“data” of Equation 5) is set as an address of the memory 350 to count the number of detection times of the valid output data by increasing a value stored in the corresponding address one by one whenever the same output data is generated. However, output data which is not included in determination of the valid range is excluded at the time of counting the number of detection times. This is to secure the reliability of the test result of the analog-to-digital converter 100 by excluding the output data which is not included in the valid range.

The calculator 330 calculates the differential non-linearity (DNL) and the integral non-linearity (INL) according to Equations 1 to 4 described above by using the output data and the number of detection times.

$$\begin{matrix}average\_count = {\sum }_{i = 0}^{N - 1} {count}_{total} / N \vert & ( Equation 1 ) \\ {normalized\_count}_{i} = {count}_{i} / average\_count & ( Equation 2 ) \\ {DNL}_{i} = {normalized\_count}_{i} - 1 & ( Equation 3 ) \\ {INL}_{i} = {\sum }_{i = 0}^{N - 1} {DNL}_{i} & ( Equation 4 )\end{matrix}$$

(i=0 to N−1, N represents the total number of output data in the measurement interval and count represents the number of detection times of the output data)

The differential non-linearity (DNL) means that distortion occurs during a process of converting any specific analog input into the digital output data and the integral non-linearity (INL) indicates how actual output data is different from ideal output data.

In Equation 1, the count of the total number of detection times of the output data is divided by the number (N) of all output data to acquire the average number of detection times (average_count). Further, when the average number of detection times acquired in Equation 1 has been already known, the average number of detection times may be used as a constant.

In Equation 2, the number (countᵢ) of detection times of i-th output data is divided by the average number (average_count) of detection times to perform a normalization process (normalized_count i).

In Equation 3, 1 is subtracted from normalized_countᵢ to acquire DNLᵢ and in Equation 4, DNLᵢ of all output data is added up to acquire the INL.

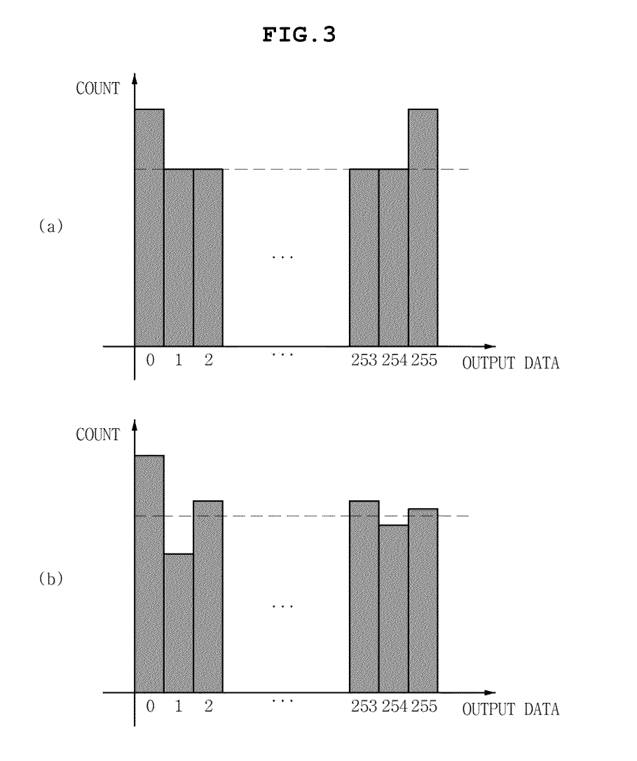

As shown in FIG. 3A, in the case of an ideal 8-bit analog-to-digital converter 100 in which a ramp signal having a predetermined slope value is applied, the number of detection times of output data (1 to 254) is constant. Therefore, respective histograms indicating the number of detection times have the same value. However, as shown in FIG. 3B, when the distortion actually occurs in the output data of the analog-to-digital converter 100, the numbers of detection times of the corresponding output data have different results and the histograms also have different values.

Therefore, in the case of the ideal analog-to-digital converter 100, the numbers of detection times are the same as each other, and as a result, the DNL and the INL are 0, but since the numbers of detection times of the output data are actually different from each other, the DNL and the INL have values other than 0.

The calculator 330 acquires the DNL and the INL through Equations 3 and 4 described above and thereafter, detects the DNL and the INL that have the maximum value in each measurement interval and transmits the detected DNL and INL to the user. The user may verify the overall performance of the analog-to-digital converter 100 by using the maximum DNL and INL.

The controller 340 controls the error detector 310, the measurer 320, and the calculator 330 so as to perform the determination of the error occurrence of the output data, the determination of the valid range, and the calculation of the DNL and the INL. In detail, the controller 340 stops driving of the error detector 310 and the measurer 320 and drives the calculator 330 by receiving the measurement complement signal of the first processor 400. That is, the controller 340 performs overall control in the measurement interval.

Further, the controller 340 performs a function to initialize variables used in the error detector 310, the measurer 320, and the calculator 330, and the memory 350. In detail, the controller 340 initializes variables such as the number of error occurrence times used in the error detector 310, the previous output data, and the degree (m) of the measurement interval used during the process of calculating the INL and the DNL, which are used in an initial driving process of the analog-to-digital converter 100.

The second processor 300 further includes the memory 350 storing the valid output data and the number of detection times. In detail, the memory 350 designates “data” (see Equation 5 described above) acquired by converting the output data of each measurement interval as the address to store the number of detection times by increasing a value stored in the address one by one whenever the valid output data is output.

For example, in the case of the 8-bit analog-to-digital converter 100, a space storing a total of 256 output data is required, but as described in the exemplary embodiment of the present disclosure, when four measurement intervals (M=4) are provided, the output data has 64 codes (2ⁿ/M) in each measurement interval to use the low-capacity memory 350.

Further, the second processor 300 may further include input and output ports for communication with an external apparatus. The input and output ports may communicate with the external apparatus in order to show the DNL and the INL detected by the calculator 330 to the user. Further, the second processor 300 may receive the measurement completion signal from the first processor 400 through the input and output ports. The input and output ports may be constituted GPIO, I2C, SPI, and the like and are not particularly limited thereto.

Hereinafter, a testing method of the analog-to-digital converter 100 according to an exemplary embodiment of the present disclosure, which includes the above configuration will be described. A description which is the same or similar as the aforementioned contents among the following description is skipped or simply described.

The testing method of the analog-to-digital converter 100 according to the exemplary embodiment of the present disclosure includes applying divided analog signals to the analog-to-digital converter 100, detecting output data in which an error occurs and valid output data based on each measurement interval output data of the analog-to-digital converter 100, and calculating a performance index of the analog-to-digital converter 100 by using the number of detection times and transmitting the calculated performance index to the outside.

In detail, variables including the number of error occurrence times and the number of measurement times used during the testing process of the analog-to-digital converter 100 are initialized and an analog signal including the divided measurement intervals and a compensation interval for consecutively outputting output data of the analog-to-digital converter 100 is generated and applied to the analog-to-digital converter 100 (S100). That is, in order to prevent the output data from being discontinuously output at a boundary point of the measurement interval due to occurrence of distortion during the conversion process, the analog signal has a compensation interval in which the output data is further output by error voltage as shown in FIG. 2. Next, a memory 350 storing the output data and the number of detection times in the respective measurement intervals is initialized (S200).

Further, the process of generating the analog signal includes generating a digital signal having the plurality of measurement intervals and converting the digital signal into the analog signal to generate the analog signal.

In a next step of initializing the memory 350, the number of detection times of the output data included in the position and a valid range of the output data in which an error occurs is counted by comparing the output data with a predetermined reference value.

The step of detecting the output data in which the error occurs and the step of counting the number of detection times of the valid output data will be described in detail. The previous output data is subtracted from the output data to acquire a difference and the difference is compared with a predetermined error threshold value (S300) to count whether the error occurs in the output data, the position of the output data in which the error occurs among the output data, and the number of error occurrence times.

When the difference is larger than the error threshold value, it is determined that the error occurs to store the output data and the previous output data in the memory 350 and increase the number of error occurrence times one by one (S400). Next, in order to determine whether the error occurs in subsequent output data, the corresponding output data is stored as the previous output data. On the contrary, when the difference is smaller than the error threshold value, it is determined that the error does not occur to store the corresponding output data as the previous output data.

It is determined whether the error occurs and thereafter, it is determined whether all output data of the analog-to-digital converter 100 in the measurement interval is included in a predetermined valid range (S500) to count the number of detection times by detecting only the output data included in the valid range among all output data of the analog-to-digital converter 100 in the measurement interval (S600). Output data which is not included in the valid range is not included in the number of detection times in order to secure reliability of a test result. The valid range is decided by Equations 5 and 6 described above.

Next, the output data and the number of detection times included in the valid range are stored in the memory 350 and it is determined whether conversion of the measurement interval is completed according to whether the analog signal reaching predetermined reference voltage (S700). In other words, when the analog signal reaches the reference voltage, since measurement of the corresponding measurement interval is completed, generation of the analog signal is stopped.

Last, differential non-linearity (DNL) and integral non-linearity (INL) which are performance indexes are calculated according to Equations 1 to 4 described above by using the output data and the number of detection times which are included in the valid range (S800). Further, INL and DNL having the maximum value among the INL and the DNL of the corresponding measurement interval are detected. Thereafter, it is determined whether testing the analog-to-digital converter is completed based on the number of measurement intervals of which measurement is completed (S900). When the number of measurement intervals of which measurement is completed is smaller than the number of all measurement intervals, the number of measurement intervals of which measurement is completed is increased by 1 in order to measure a subsequent measurement interval and the process returns to step S200 of initializing the memory 350.

Since the apparatus for testing the analog-to-digital converter 100 according to the exemplary embodiment of the present disclosure applies the divided analog signals to the analog-to-digital converter 100, the apparatus for testing the analog-to-digital converter 100 may store only the output data of the corresponding measurement interval to perform a test by using the low-capacity memory 350.

Further, since the analog signal has a separate compensation interval so as to consecutively output the output data, there is no output data which is skipped when the distortion occurs during the converting process, and as a result, the reliability of the test result is improved.

In addition, according to the exemplary embodiment of the present disclosure, it is determined whether the error occurs in the output data and it is determined whether all output data in the measurement interval are included in the valid range to acquire the test result based on accurate output data.

Although the exemplary embodiment of the present disclosure has been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. An apparatus for testing an analog-to-digital converter, the apparatus comprising:
an analog-to-digital converter converting an analog type signal into a digital type signal;
a signal generator applying a predetermined type analog signal to the analog-to-digital converter; and
a first processor controlling the signal generator so that the analog signal is divided to have at least two measurement intervals.

2. The apparatus of claim 1, wherein the first processor controls the signal generator to generate the analog signal including divided measurement intervals and a compensation interval for securing a consecutive output of the analog-to-digital converter and apply the generated analog signal to the analog digital converter.

3. The apparatus of claim 2, further comprising:
a second processor determining whether an error occurs in the output data by comparing the output data of the analog-to-digital converter with a predetermined reference value and whether all output data of the analog-to-digital converter in the measurement interval are valid.

4. The apparatus of claim 3, wherein:
the second processor includes
an error detector counting whether the error occurs in the output data, the position of output data in which the error occurs among the output data, and the number of occurrence times of the error by comparing a difference between the output data and the previous output data of the output data with a predetermined error threshold value;
a measurer determining whether all of the output data of the analog-to-digital converter in the measurement interval is included in a predetermined valid range to detect only output data included in the valid range among the output data in which the error occurs and count the number of detection times;
a calculator calculating differential non-linearity (DNL) and integral non-linearity (INL) according to Equations 1 to 4 described below by using the output data and the number of detection times; and
a controller controlling driving of the error detector, the measurer, and the calculator so as to perform the determination of the error occurrence of the output data, the determination of the valid range, and the calculation of the DNL and the INL.
$$\begin{matrix}average\_count = {\sum }_{i = 0}^{N - 1} {count}_{total} / N \vert & ( Equation 1 ) \\ {normalized\_count}_{i} = {count}_{i} / average\_count & ( Equation 2 ) \\ {DNL}_{i} = {normalized\_count}_{i} - 1 & ( Equation 3 ) \\ {INL}_{i} = {\sum }_{i = 0}^{N - 1} {DNL}_{i} & ( Equation 4 )\end{matrix}$$
(i=0 to N−1, N represents the total number of output data in the measurement interval and count represents the number of detection times of the output data)

5. The apparatus of claim 4, wherein the second processor further includes a memory storing the output data and the number of detection times.

6. The apparatus of claim 1, wherein:
the signal generator includes
a digital signal generator generating divided digital signals, and
a digital-to-analog converter converting the digital signal into the analog signal type.

7. The apparatus of claim 1, wherein the analog signal is a ramp signal having a predetermined slope.

8. A testing method of an analog-to-digital converter, the testing method comprising:
a preparation step of applying divided analog signals to the analog-to-digital converter;
an error determining step of determining whether an error occurs in the output data by comparing output data of the analog-to-digital converter with a predetermined reference value and whether all output data of the analog-to-digital converter in the measurement interval are valid; and
a calculation step of calculating a performance index of the analog-to-digital converter based on the output data.

9. The testing method of claim 8, wherein:
the preparation step includes
a signal generating step of applying an analog signal divided into divided measurement intervals and a compensation interval for securing a consecutive output of the analog-to-digital converter to the analog-to-digital converter, and
a step of initializing a memory storing the output data and the number of detection times.

10. The testing method of claim 9, wherein:
the signal generating step includes
generating divided digital signals, and
converting the digital signal into the analog signal.

11. The testing method of claim 8, wherein the analog signal is a ramp signal having a predetermined slope value.

12. The testing method of claim 8, wherein:
the error determining step includes
counting whether the error occurs in the output data, the position of output data in which the error occurs among the output data, and the number of occurrence times of the error by comparing a difference between the output data and the previous output data of the output data with a predetermined error threshold value,
determining whether all of the output data of the analog-to-digital converter in the measurement interval is included in a predetermined valid range to detect only output data included in the valid range among the output data of the analog-to-digital converter in the measurement interval and count the number of detection times,
storing in a memory the output data and the number of detection times included in the valid range, and
determining whether conversion of a measurement interval is completed according to whether the analog signal reaching predetermined reference voltage.

13. The testing method of claim 8, wherein:
the calculation step includes
calculating differential non-linearity (DNL) and integral non-linearity (INL) which are performance indexes according to Equations 1 to 4 described below by using the output data and the number of detection times, and
determining whether testing the analog-to-digital converter is completed based on the number of measurement intervals in which measurement is completed.
$$\begin{matrix}average\_count = {\sum }_{i = 0}^{N - 1} {count}_{total} / N \vert & ( Equation 1 ) \\ {normalized\_count}_{i} = {count}_{i} / average\_count & ( Equation 2 ) \\ {DNL}_{i} = {normalized\_count}_{i} - 1 & ( Equation 3 ) \\ {INL}_{i} = {\sum }_{i = 0}^{N - 1} {DNL}_{i} & ( Equation 4 )\end{matrix}$$
(i=0 to N−1, N represents the total number of output data in the measurement interval and count represents the number of detection times of the output data)
